(19) United States
(12) Patent Application Publication
(10) Pub. No.: US 2005/0161250 A1
(43) Pub. Date: Jul. 28, 2005

(54) Printed circuit board, method and apparatus for fabricating the same, wiring circuit pattern, and printed wiring board

(75) Inventor: Masami Hiramoto, Yamanashi-ken (JP)

Correspondence Address: Charles N.J. Ruggiero, Esq.;Ohlandt, Greeley, Ruggiero & Perle, L.L.P., One Landmark Square, 10th Floor, Stamford, CT, 06901-2682, US

(73) Assignee: CASIO MICRONICS CO., LTD.

(21) Appl. No.: 10/842,730

(22) Filed: May 10, 2004

(30) Foreign Application Priority Data
Jan. 23, 2004 (JP) 2004-015581

(51) Int. Cl. H05K 1/11; H01B 13/00

(52) U.S. Cl. 174/250; 216/13; 216/41

(57) ABSTRACT

A wiring circuit pattern of this invention is formed by forming a resin resist pattern film on a conductor layer of a base of a printed circuit board in which at least an insulating layer and the conductor layer are stacked on at least one surface of the base, and performing wet etching by using the formed resin resist pattern film as an etching resist, wherein the width of the top of the wiring circuit pattern is larger than the width of its bottom.

### CROSS-REFERENCE TO RELATED APPLICATIONS

This application is based upon and claims the benefit of priority from prior Japanese Patent Application No. 2004-015581, filed Jan. 23, 2004, the entire contents of which are incorporated herein by reference.

### BACKGROUND OF THE INVENTION

1. Field of the Invention

The present invention relates to a printed circuit board, a method and apparatus for fabricating it, a wiring circuit pattern, and a printed wiring board and, more particularly, to a printed circuit board and printed wiring board suited to improving the etching factor, a method and apparatus for fabricating the printed circuit board, and a printed circuit board fabricated by these method and apparatus.

2. Description of the Related Art

Printed circuit boards such as carrier tapes for TAB, carrier tapes for COF (Chip On Film), and FPCs (Flexible Print Circuits) are used in various applications such as monitors, liquid crystal drivers of portable apparatuses and the like, semiconductor ICs, and cables for connecting parts.

On a printed circuit board of this type, as shown in FIGS. 1 to 6, a wiring circuit is generally formed through steps of coating a conductor layer such as a copper foil with a photoresist (photosensitive agent), exposing wiring circuit patterns to light, and developing and etching the exposed patterns.

FIGS. 1 and 2 are sectional views taken along the widthwise direction of the board. FIG. 1 shows an example of a two-layered carrier tape. On an insulating layer 10 made of, e.g., polyimide, which serves as a base 14 of a printed circuit board, a conductor layer 12 made of, e.g., copper, which is formed into predetermined wiring circuit patterns is stacked. The surface of the conductor layer 12 is cleaned by degreasing, chemical polishing, or the like. The thickness of the copper conductor layer 12 is, e.g., about 8 to 12 μm, and the thickness of the polyimide insulating layer 10 is, e.g., about 25 to 50 μm.

FIG. 2 shows an example of a three-layered carrier tape in which an adhesive layer 16 for adhering an insulating layer 10 and conductor layer 12 is formed between them. In this structure, the thickness of the conductor layer 12 made of copper is, e.g., about 15 to 25 μm, the thickness of the insulating layer 10 made of polyimide is, e.g., about 75 μm, and the thickness of the adhesive layer 16 is, e.g., 12 μm.

The tape width and length of these two- and three-layered carrier tapes are about 35 to 350 mm and about 100 to 400 m, respectively. Sprocket holes 18 for reel-to-reel conveyance are formed at predetermined intervals on the two sides along the longitudinal direction of the tape.

Subsequently, as shown in FIG. 3, the surface of the conductor layer 12 is coated with a photoresist 20 about 4 μm thick except for the tape sides in which the sprocket holes 18 are formed. After that, as shown in FIG. 4, the photoresist 20 is irradiated with ultraviolet radiation 24 through a photomask 22 having predetermined wiring circuit patterns. Consequently, as shown in FIG. 4, the wiring circuit patterns are printed on the photoresist 20.

As shown in FIG. 5, the photoresist 20 is developed by using a developer 27 to leave photoresists 20(#a) in portions corresponding to the wiring circuit patterns. In addition, as shown in FIG. 6, etching is performed using an etchant by a method such as dipping or spraying. The wiring circuit patterns formed in FIG. 5 are covered with the photoresists 20(#a) and not touched by the etchant. Therefore, the etching progresses only on portions where the holes are formed in the conductor layer 12. Finally, as shown in FIG. 6, the conductor layer 12 is removed from portions except for the wiring circuit patterns. After that, the remaining photoresists 20 (#a) are removed. In this way, conductor layers 12(#a) formed into the predetermined wiring circuit patterns are obtained on the insulating layer 10.

As described previously, many copper foils used as the conductor layer 12 in the two-layered carrier tape have a thickness of about 8 to 12 μm. As the thickness of the copper foil increases, it becomes more difficult to obtain a fine wiring pitch. As the thickness of the copper foil decreases, fine wiring pitch patterns become easier to form. On the other hand, many copper foils used as the conductor layer 12 in the three-layered carrier tape have a thickness of 15 to 25 μm. Since no fine patterns can be formed, this three-layered carrier tape is unsuited to obtaining a fine wiring pitch. For this reason, two-layered carrier tapes are beginning to be extensively used-in general purposes. In the three-layered carrier tape, the adhesive layer 16 is formed between the conductor layer 12 and insulting layer 10, and the conductor layer 12 and insulating layer 10 must be laminated. So, decreasing the thickness of the conductor layer 12 makes the lamination difficult and prolongs the subsequent fabrication process, resulting in many demerits. Therefore, two-layered carrier tapes are currently most frequently used.

Presently, the minimum wiring pitch is 40 μm in three-layered carrier tapes (when a copper foil 15 μm thick is used as the conductor layer 12), and 30 μm in two-layered carrier tapes (when a copper foil 8 μm thick is used as the conductor layer 12). These values are the limits of the present fabrication methods. If a carrier tape material having a thin copper foil (less than 8 μm) is used, a wiring pitch smaller than 30 μm is possible. However, the copper foil cannot be simply thinned when applications of devices are taken into consideration. This is so because ACF bonding is used as a method of bonding LCD panel terminals or LSIs, and this leads to short circuits by conductive particles. Accordingly, a technique capable of processing fine patterns with thick copper foils is being demanded.

Unfortunately, the conventional printed circuit board fabrication method as described above has the following problems.

FIG. 7 is a partially enlarged sectional view of a printed circuit board fabricated by the conventional fabrication method as described above. That is, in this conventional fabrication method, as indicated by the base 14 in the upper half of FIG. 7, a difference is produced between the top width and bottom width of the conductor layers 12(#a) forming wiring circuit patterns; the bottom width is always larger than the top width. Letting ET and EB be the top width and bottom width, respectively, after etching is performed, ET<EB always holds in a general etching method by which an etchant is used by dipping or spraying. An etching factor Ef represented by
Ef=EH/((EB−ET)/2) (1)
by using ET, EB, and a thickness EH of the conductor layer 12 is an index for evaluating the quality of the finished pattern. Note that EP shown in FIG. 7 is the wiring pitch of the wiring circuit patterns.

Ef is generally about half the conductor thickness EH. Although ET=EB is ideal, this is not easy to realize. In particular, the wiring pitch EP of the wiring circuit patterns becomes finer, it becomes more difficult to raise Ef. This makes stable fabrication of wiring circuit patterns on wide carrier tapes impossible. As indicated by the base 14 in the upper half of FIG. 7, in the conventional method, Ef is about half the thickness EH of the conductor layers 12(#a). This increases EB and, as a consequence, decreases a wiring pattern interval LS.

For example, the wiring pattern interval LS is about 2.0 μm when the thickness EH of the conductor layers 12(#a) is 8 μm, the wiring pitch EP is 20 μm, the top width ET of the conductor layers 12(#a) is 10 μm, and the etching factor Ef is 2. Since electro-migration readily occurs when the wiring pattern interval LS is 2.0 μm, the inter-wiring insulation resistance cannot be maintained at 10⁹ Ω and reduces to 10⁴ to 10⁶. This deteriorates the reliability.

To solve the above problem, the wiring pattern interval LS need only be increased. As indicated by the base 14 in the lower half of FIG. 7, the wiring pattern interval LS can be increased by extending the etching time, i.e., by performing overetching. For example, to perform etching such that the wiring pattern interval LS is 10.0 μm when the etching factor Ef is 2.0, it is only necessary to extend the wiring pattern internal LS by 4.0 μm on each side, i.e., extend it by about 8.0 μm on the two sides. Since an interval of 2.0 μm is originally obtained, the wiring pattern interval LS in this case is 10.0 μm. That is, overetching need only be performed such that the bottom width EB of each conductor layer 12(#a) decreases by a total of 8.0 μm.

Unfortunately, decreasing the bottom width EB also decreases the top width ET by about 8.0 μm, and this inevitably decreases the top width after etching ET to about 2.0 μm. Consequently, the vertical sectional shape in the widthwise direction of the wiring pattern becomes an triangle. A wiring pattern having this inverted triangular sectional shape causes the following inconveniences in the subsequent steps.

That is, to achieve their purposes, wiring patterns must be electrically bonded to active parts such as semiconductor chips and passive parts such as resistors and capacitors. Bonding methods are welding bonding using a soldering material, and contact bonding using so-called NCP (Non Conductive Paste) which is an insulating adhesive having an adhering function, so-called ACF (Anisotropic Conductive Film) having an adhering function and contained by electrically mixing conductive particles in an insulating resin, or ACP (Anisotropic Conductive Paste).

When wiring patterns having a substantially triangular sectional shape are bonded by the welding method such as solid phase diffusion or liquid phase diffusion bonding, the bonding area decreases, and this lowers the bonding strength. Also, since the bonded portion is not a “surface” but a “line”, the connection area sharply decreases to make the resistance very high. These tendencies significantly appear in AuSn eutectic alloy bonding which is currently most-frequently used, so bonding is practically impossible.

Similarly, when bonding is performed using NCP, the bonded portion is not a “surface” but a “line”. Accordingly, the connection area sharply decreases to make the resistance very high, so bonding is practically impossible.

Furthermore, when bonding is performed using ACP, the shape of contained conductive particles is generally a “sphere”. Therefore, no conductive particle can be put on the conductive layer 12(#a) having a top width ET of 2.0 μm. That is, no conductive particle can exist on the bonded portion, and this makes any electrical connection impossible.

### BRIEF SUMMARY OF THE INVENTION

The present invention has been made in consideration of the above situation, and has as its object to provide a printed circuit board having a wiring pattern by which the etching factor is improved, and which does not deteriorate the migration resistance and bonding properties even when the wiring pitch is made fine, and to provide a method and apparatus for fabricating the printed circuit board, and a wiring circuit pattern.

Examples of the prior art having similar objects are Jpn. Pat. Appln. KOKAI Publication Nos. 2001-94234 and 63-153889.

To achieve the above object, the present invention uses the following means.

That is, according to the first aspect of the present invention, there is provided a wiring circuit pattern formed by forming a resin resist pattern film on a conductor layer of a base of a printed circuit board in which at least an insulating layer and the conductor layer are stacked on at least one surface of the base, and performing wet etching by using the formed resin resist pattern film as an etching resist, wherein a width of a top of the wiring circuit pattern is larger than a width of its bottom.

According to the second aspect of the present invention, in the wiring circuit pattern of the first aspect, a board formed by impregnating glass fibers with a resin such as an epoxy resin and having no light transmittance is used.

According to the third aspect of the present invention, in the wiring circuit pattern of the first aspect, a board using engineering plastic containing at least polyimide, Polyethylene Terephtalate, or Polyethylene Naphtalate and having light transmittance is used.

According to the fourth aspect of the present invention, there is provided a wiring circuit pattern formed by forming a resin resist pattern film on a conductor layer of a base of a printed circuit board in which at least an insulating layer and the conductor layer are stacked on at least one surface of the base, and performing wet etching by using the formed resin resist pattern film as an etching resist, wherein at least a vertical sectional shape in a widthwise direction of the wiring circuit pattern is a substantially inverted trapezoidal shape.

According to the fifth aspect of the present invention, there is provided a wiring circuit pattern formed by forming a resin resist pattern film on a conductor layer of a base of a printed circuit board in which at least an insulating layer and the conductor layer are stacked on at least one surface of the base, and performing wet etching by using the formed resin resist pattern film as an etching resist, wherein at least a vertical sectional shape in a widthwise direction of the wiring circuit pattern is a substantially horn shape.

According to the sixth aspect of the present invention, there is provided a wiring circuit pattern formed by forming a resin resist pattern film on a conductor layer of a base of a printed circuit board in which at least an insulating layer and the conductor layer are stacked on at least one surface of the base, and performing wet etching by using the formed resin resist pattern film as an etching resist, wherein at least a vertical sectional shape in a widthwise direction of the wiring circuit pattern is a substantially hourglass shape.

In the wiring circuit patterns according to the first to sixth aspects, therefore, the etching factor can be improved by the means as described above.

According to the seventh aspect of the present invention, there is provided a printed wiring board formed by forming a resin resist pattern film on a conductor layer of a base of a printed circuit board in which at least an insulating layer and the conductor layer are stacked on at least one surface of the base, and performing wet etching by using the formed resin resist pattern film as an etching resist, wherein at least a vertical sectional shape in a widthwise direction of the printed wiring board is a substantially inverted trapezoidal shape, and a space formed between wiring circuit patterns has a substantially trapezoidal shape.

According to the eighth aspect of the present invention, in the printed wiring board of the seventh aspect, an area of the substantially trapezoidal shape is equal to or larger than an area of the substantially inverted trapezoidal shape.

According to the ninth aspect of the present invention, there is provided a printed wiring board formed by forming a resin resist pattern film on a conductor layer of a base of a printed circuit board in which at least an insulating layer and the conductor layer are stacked on at least one surface of the base, and performing wet etching by using the formed resin resist pattern film as an etching resist, wherein at least a vertical sectional shape in a widthwise direction of the printed wiring board is a substantially horn shape, and a space formed between wiring circuit patterns has a substantially bowl shape.

According to the 10th aspect of the present invention, in the printed wiring board of the ninth aspect, an area of the substantially bowl shape is equal to or larger than an area of the substantially horn shape.

According to the 11th aspect of the present invention, there is provided a printed wiring board formed by forming a resin resist pattern film on a conductor layer of a base of a printed circuit board in which at least an insulating layer and the conductor layer are stacked on at least one surface of the base, and performing wet etching by using the formed resin resist pattern film as an etching resist, wherein at least a vertical sectional shape in a widthwise direction of the printed wiring board is a substantially hourglass shape, and a space formed between wiring circuit patterns has a substantially barrel shape.

According to the 12th aspect of the present invention, in the printed wiring board of the 11th aspect, an area of the substantially barrel shape is equal to or larger than an area of the substantially hourglass shape.

In the printed wiring boards according to the seventh to 12th aspects, the etching factor can be improved by the means as described above.

According to the 13th aspect of the present invention, there is provided a printed circuit board fabrication apparatus comprising resin resist pattern forming means for forming a resin resist pattern film on a conductor layer of a base of a printed circuit board obtained by stacking at least an insulating layer and the conductor layer and first etching means for etching away a portion of a film thickness of the conductor layer by using the resin resist pattern film formed by the resin resist pattern forming means as an etching resist. The apparatus further comprises pressing means for heating the base, from which the portion of the film thickness of the conductor layer is etched away by the first etching means, to a temperature equal to or higher than a softening temperature of the resin resist pattern film, and pressing the resin resist pattern film against the conductor layer, thereby allowing the resin resist pattern film to cover surfaces of the conductor layer in contact with the resin resist pattern film, and second etching means for etching away the rest of the film thickness of the conductor-layer from which the portion of the film thickness is etched away by the first etching means, thereby forming a predetermined wiring circuit pattern by the conductor layer.

In the printed circuit board fabrication apparatus of the 13th aspect having the means as described above, therefore, the first etching means etches away only a portion of the film thickness of the conductor layer on which no resin resist pattern is formed. Accordingly, etching can be temporarily stopped while a large ET value is ensured. Subsequently, the pressing means allows the resin resist pattern film to cover the top and side walls of the conductor layer. Since the resin resist pattern film barriers the top and side walls of the conductor layer, etching performed by the second etching means can be stopped in these portions. Consequently, the top width of the conductor layer is ensured, and the etching factor can be improved. Therefore, even when the wiring pitch is made fine, it is possible to prevent deterioration of the insulation resistance reliability and test reliability of the printed circuit board.

According to the 14th aspect of the present invention, there is provided a printed circuit board fabrication method comprising a resin resist pattern formation step of forming a resin resist pattern film on a conductor layer of a base of a printed circuit board obtained by stacking at least an insulating layer and the conductor layer and a first etching step of etching away a portion of a film thickness of the conductor layer by using the resin resist pattern film formed in the resin resist pattern formation step as an etching resist. The method further comprises a pressing step of heating the base, from which the portion of the film thickness of the conductor layer is etched away in the first etching step, to a temperature equal to or higher than a softening temperature of the resin resist pattern film, and pressing the resin resist pattern film against the conductor layer, thereby allowing the resin resist pattern film to cover surfaces of the conductor layer in contact with the resin resist pattern film, and a second etching step of etching away the rest of the film thickness of the conductor layer from which the portion of the film thickness is etched away in the first etching step, thereby forming a predetermined wiring circuit pattern by the conductor layer.

In the printed circuit board fabrication method of the 14th aspect having the steps as described above, therefore, in the first etching step, only a portion of the film thickness of the conductor layer on which no resin resist pattern is formed is etched away. Accordingly, etching can be temporarily stopped while a thick ET is ensured. Subsequently, in the pressing step, the resin resist pattern film covers the top and side walls of the conductor layer. Since the resin resist pattern film barriers the top and side walls of the conductor layer, etching performed in the second etching step can be stopped in these portions. Consequently, the top width of the conductor layer is ensured, and the etching factor can be improved. Therefore, even when the wiring pitch is made fine, it is possible to prevent deterioration of the insulation resistance reliability and test reliability of the printed circuit board.

According to the 15th aspect of the present invention, there is provided a printed circuit board fabrication method comprising a resin resist pattern formation step of forming a resin resist pattern film on a conductor layer of a tape-like base of a printed circuit board obtained by stacking at least an insulating layer and the conductor layer and a first etching step of etching away a portion of a film thickness of the conductor layer by using the resin resist pattern film formed in the resin resist pattern formation step as an etching resist. The method further comprises a winding step of winding the tape-like base on a reel while applying tension in a longitudinal direction of the base, and a pressing step of heating the base wound on the reel such that the resin resist pattern film is heated to a temperature equal to or higher than its softening temperature, thereby softening the resin resist pattern film, and allowing the softened resin resist pattern film to cover surfaces in contact with the resin resist pattern film by the tension. In addition, the method also includes a second etching step of etching away the rest of the film thickness of the conductor layer from which the portion of the film thickness is etched away in the first etching step, thereby forming a predetermined wiring circuit pattern by the conductor layer.

In the printed circuit board fabrication method of the 15th aspect having the steps as described above, therefore, in the pressing step, a pressure is applied to the base by the tension applied in the winding step, without using any special pressing mechanism. As a consequence, the top and side walls of the conductor layer can be covered with the resin resist pattern film.

According to the 16th aspect of the present invention, there is provided a printed circuit board fabricated by the printed circuit board fabrication method of the 14th or 15th aspect.

Since, therefore, the printed circuit board of the 16th aspect is fabricated by the printed circuit board fabrication method according to the 14th or 15th aspect as described above, the etching factor can be improved. Consequently, even when the wiring pitch is made fine, deterioration-of the insulation resistance reliability and test reliability can be prevented.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention and, together with the general description given above and the detailed description of the preferred embodiments given below, serve to explain the principles of the invention.

FIG. 1 is a vertical sectional view of a two-layered carrier tape taken along the widthwise direction of a board;

FIG. 2 is a vertical sectional view of a three-layered carrier tape taken along the widthwise direction of the board;

FIG. 3 is a vertical sectional view of the board when it is coated with a photoresist;

FIG. 4 is a vertical sectional view of the board during exposure;

FIG. 5 is a vertical sectional view of the board during development;

FIG. 6 is a vertical sectional view of the board during etching;

FIG. 7 is a partial sectional view of a printed circuit board fabricated by the conventional fabrication method;

FIG. 8 is a flow chart showing an example of the flow of processing of a printed circuit board fabrication method according to the first embodiment;

FIG. 9 is an enlarged sectional view taken along the widthwise direction of a carrier tape in a first etching process;

FIG. 10 is a schematic view showing the arrangement of an apparatus used in a heating/pressing process;

FIG. 11 is a vertical sectional view of the board before the heating/pressing process;

FIG. 12 is a vertical sectional view of the board after the heating/pressing process;

FIG. 13 is a schematic view showing the arrangement of a modification of the apparatus used in the heating/pressing process;

FIG. 14 is a vertical sectional view of the board in a second etching process;

FIG. 15 is a vertical sectional view showing an example of a board on which the top width of a conductor-layer is larger than its bottom-width;

FIG. 16 is a vertical sectional view showing an example of a board on which a central portion of a conductor layer is narrow and its top width and bottom width are substantially equal;

FIG. 17 is a schematic view showing the arrangement of an apparatus for performing the first etching process, heating/pressing process, and second etching process;

FIG. 18 is a schematic view showing the arrangement of a reel of a heating/pressing apparatus according to the second embodiment;

FIG. 19 is a schematic view showing the arrangement of a constant-temperature bath of the heating/pressing apparatus according to the second embodiment;

FIG. 20 is a schematic view for explaining a cooling method of the heating/pressing apparatus according to the second embodiment;

FIG. 21 is a schematic view showing an example of the arrangement, before heating, of a heating/pressing apparatus according to the third embodiment;

FIG. 22 is a schematic view showing the arrangement of a constant-temperature bath applied to the heating/pressing apparatus according to the third embodiment; and

FIG. 23 is a schematic view showing an example of the arrangement, after heating, of the heating/pressing apparatus according to the third embodiment.

### DETAILED DESCRIPTION OF THE INVENTION

The best mode for carrying out the present invention will be described below with reference to the accompanying drawing.

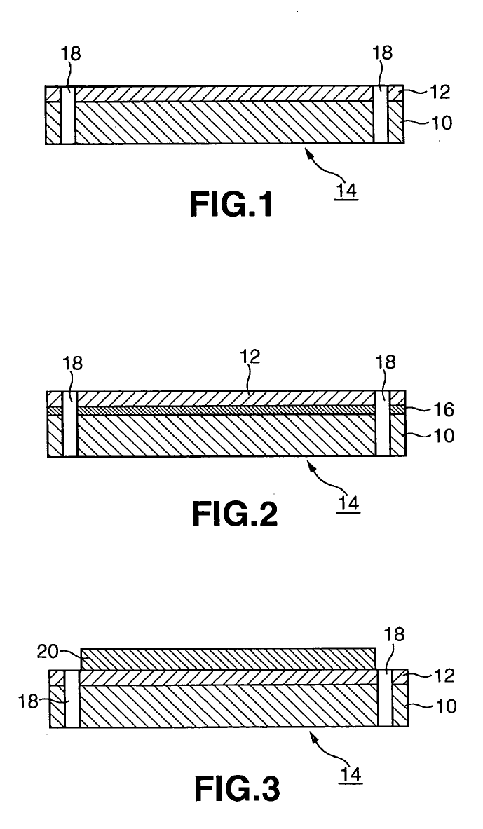

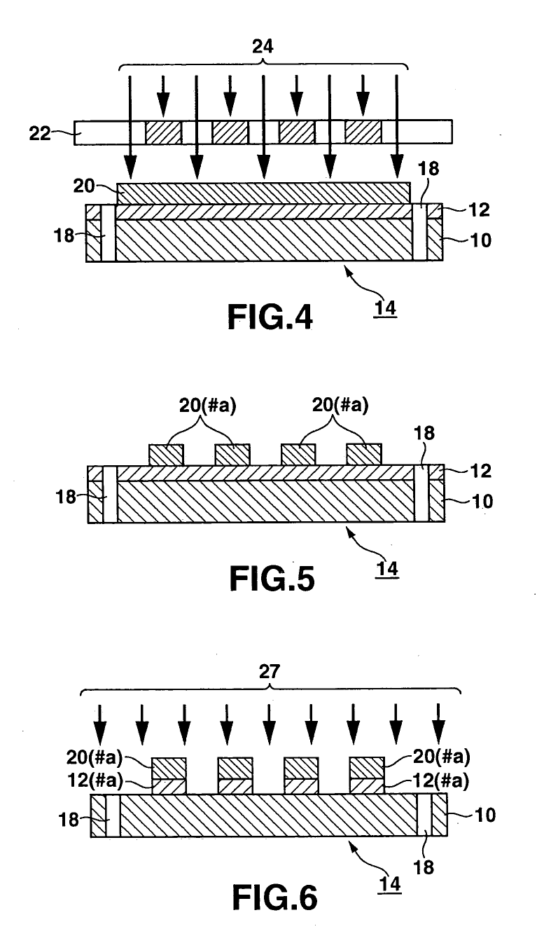

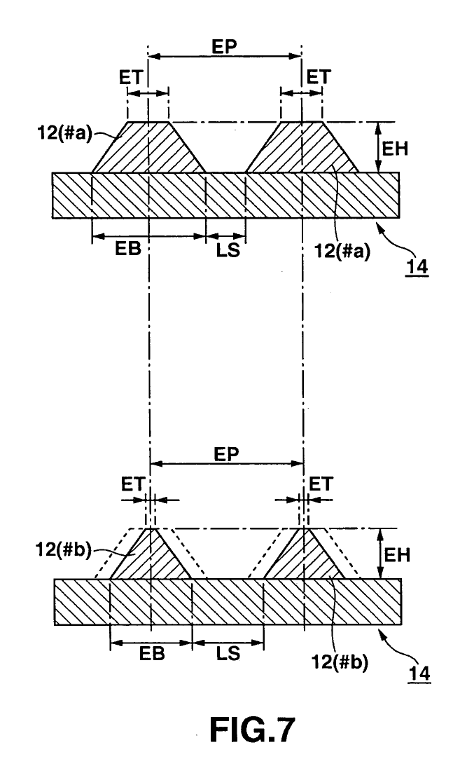

In the following explanation of embodiments, the same reference numerals as in FIGS. 1 to 7 denote the same pats.

### First Embodiment

The first embodiment of the present invention will be described below.

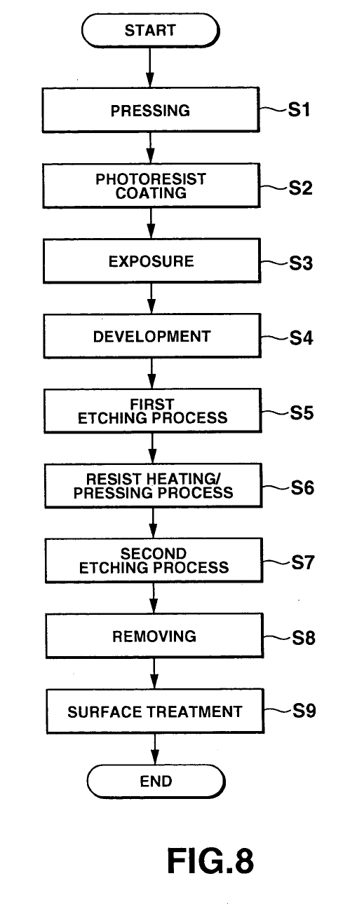

FIG. 8 is a flow chart showing an example of the flow of processing of a printed circuit board fabrication method according to this embodiment.

That is, in a printed circuit board having a wiring pattern according to this embodiment, an underlying metal layer (not shown) is formed on an insulating layer 10 to have a thickness of 10 to 500 Å (1 Å=10⁻⁸ cm) by a thin film formation method such as sputtering by using a metal material such as NiCr, Ni, Cr, Ti, or W. On this underlying metal layer, a conductive layer is successively formed to have a thickness of a few thousand Å to about 1.0 μm by the same method as above, e.g., sputtering, by using a conductive material such as Cu or Ni.

A final conductive layer 12 about 5 to 35 μm thick is then formed by plating by using a conductive material such as Cu or Ni. Subsequently, a predetermined metal mold and press machine (not shown) or a UV-YAG laser processor (not shown) is used to form sprocket holes 18 having a predetermined shape in predetermined positions on the two sides in the longitudinal direction of at least a base 14. In this manner, the base 14 is formed (S1).

In addition, after pre-processing (not shown) such as electropolishing, the surface of the conductive layer 12 is coated with a resist (e.g., PMER-P-RZ: manufactured by TOKYO OHKA KOGYO) by using a coating method such as roll coating or spin coating, and the resist is prebaked (hardened), thereby forming a photoresist 20 about 3 to 5 μm thick (S2). Then, exposure is performed using a predetermined glass mask (S3), and a first etching process is performed (S5) after development (S4).

After that, the processing is complete by performing a resist heating/pressing process (S6), a second etching process (S7), removing of the photoresist 20 (S8), and a surface treatment (S9) by, e.g., electroplating, electroless plating, or nanopaste printing. Note that the processes in steps S1 to S4, S8, and S9 are already described, so a repetitive explanation thereof will be omitted.

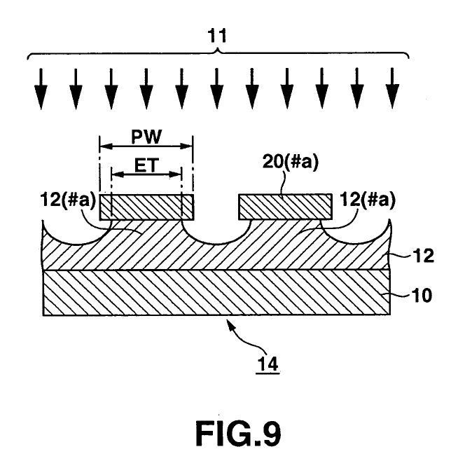

In the first etching process in step S5, as shown in FIG. 9 which is an enlarged sectional view taken along the carrier tape widthwise direction, only a portion of the film thickness of the perforated conductor layer 12 is etched away. In this manner, half etching is performed by so-called dipping etching, shower etching, or the like by which no complete wiring circuit patterns are formed. By this half etching, a width PW of each photoresist 20(#a) of wiring circuit patterns becomes larger than a top width ET of a corresponding conductor layer 12(#a).

For example, this half etching process is performed using exactly the same etching apparatus as the prior art. The etching conditions are that the first etching process is performed by using a cupric chloride-based etchant 11 by the shower etching method at a liquid temperature of 35° C. and a spray pressure of 0.11 MPa for an etching time of about 20 to 40 sec. As a consequence, the base 14 is processed as shown in FIG. 9.

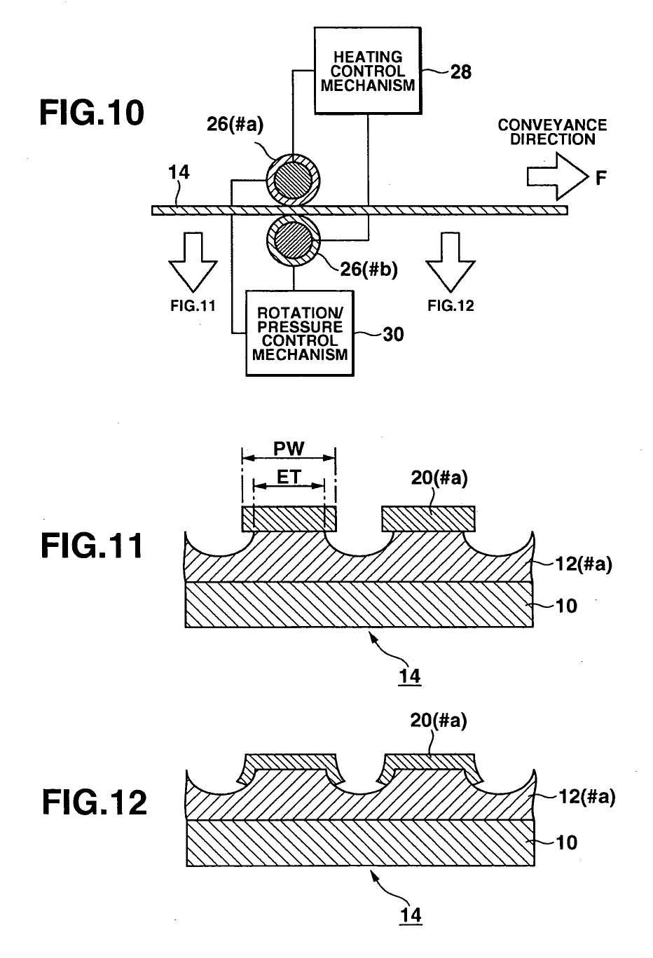

The thus half-etched base 14 is conveyed to a heating/pressing apparatus as shown in FIG. 10 in which the resist heating/pressing process in step S6 is performed.

This heating/pressing apparatus includes a conveyor mechanism (not shown), and a pair of opposing heating/pressing rollers 26(#a) and 26(#b) each having a surface coated with a heat-resistant elastic material (not shown) (e.g., Rubber Sheet: manufactured by Shin-Etsu Polymer). The heating/pressing apparatus further includes a heating control mechanism 28 for controlling the heating amount of the heating/pressing rollers 26(#a) and 26(#b) having the surfaces coated with the heat-resistant elastic material (not shown) (e.g., Rubber Sheet: manufactured by Shin-Etsu Polymer), and a rotation/pressure control mechanism 30 for controlling the rotating force and pressing force of the heating/pressing rollers 26(#a) and 26(#b).

When the heating/pressing apparatus receives the base 14 having undergone the half-etching process in step S5, the conveyor mechanism (not shown) introduces the base 14 between the pair of heating/pressing rollers 26(#a) and 26(#b) along a conveyance direction F shown in FIG. 10. The rotation/pressure control mechanism 30 controls the pressure that the pair of heating/pressing rollers 26(#a) and 26(#b) apply to the base 14 introduced between them. The rotation/pressure control mechanism 30 also controls the two rollers 26(#a) and 26(#b) to rotate in the direction F at a speed matching the conveyance of the base 14. Furthermore, the heating control mechanism 28 controls the two rollers 26(#a) and 26(#b) to heat the base 14 introduced between them to a temperature equal to or higher than the softening temperature of the photoresist 20 and lower than the softening temperature of the conductor layer 12.

When the base 14 is introduced between the two rollers 26(#a) and 26(#b) having the surfaces coated with the heat-resistant elastic material (not shown) (e.g., Rubber Sheet: manufactured by Shin-Etsu Polymer) of the heating/pressing apparatus constructed as above, the two rollers 26(#a) and 26(#b) apply a temperature of 50° C. to 100° C., preferably, 80° C. to 90° C., which is equal to or higher than the softening temperature and lower than the melting temperature of the photoresist 20, and apply a load of about 5 to 100 Kg which depends upon the tape width, to the base 14, thereby heating and pressing the base 14 for about 2 to 8 sec.

Consequently, each photoresist 20(#a) is pressed against a corresponding conductor layer 12(#a) to cover not only the top but also the side walls of the corresponding conductor layer 12(#a). In this way, before and after the heating/pressing rollers 26(#a) and 26(#b), the sectional shape of the base 14 changes from a sectional shape shown in FIG. 11 to a sectional shape as shown in FIG. 12.

The photoresists 20(#a) are pressed and heated for the reasons explained below. That is, to allow each photoresist 20(#a) to cover not only the top but also the side walls of a corresponding conductor layer 12(#a) by only heating without any pressing, the photoresist 20(#a) must be melted first. The photoresists 20(#a) used in this embodiment are surely melted when heated to 100° C. However, the top and side walls of the conductor layer 12(#a) cannot be evenly covered only by melting the photoresist 20(#a). That is, in the longitudinal direction of the side walls of the conductor layer 12(#a), the end portions of the photoresist 20(#a) form not uniform straight lines but waves in the longitudinal direction. If the end portions of the photoresist 20(#a) are not uniform straight lines, etching cannot be evenly performed in the subsequent second etching process. In the worst case, therefore, the top of each conductor layer 12(#a) cannot be formed straight. It is also difficult to evenly and stably remove the photoresists 20(#a) which are once melted. When simply heated to a temperature equal to or higher than its softening point and lower than its melting point, the photoresist 20(#a) cannot evenly cover not only the tops but also the side walls of the conductor layer 12(#a).

Accordingly, to evenly cover not only the top but also the side walls of the conductor layer 12(#a) and evenly and stably remove the photoresist 20(#a), it is necessary to heat the photoresist 20(#a) to a temperature equal to or higher than its softening temperature and lower than its melting temperature, and apply a load of about 5 to 100 Kg which depends upon the tape width. The base 14 in which the photoresists 20(#a) are thus pressed is then conveyed to an apparatus for performing the second etching process by the conveyor mechanism (not shown).

As a modification, it is also possible to preheat the base 14 by using a preheating device which uses hot wind, IR, or the like, and introduce the base 14 between the heating/pressing rollers 26(#a) and 26(#b) after that. In this case, the preheating apparatus need not heat by a heat amount with which the temperature of the photoresist 20 becomes equal to or higher than the softening temperature; the heat amount can be smaller than that. When the base 14 is thus preheated before being introduced between the heating/pressing rollers 26(#a) and 26(#b), the photoresists 20(#a) can be adhered more tightly to the conductor layers 12(#a) when pressed by the heating/pressing rollers 26(#a) and 26(#b).

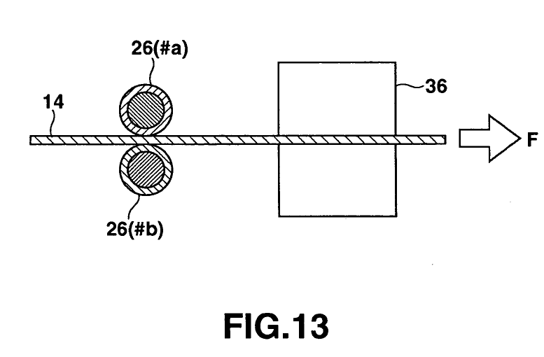

Alternatively, as shown in FIG. 13, it is possible to cool the pressed base 14 by a cooling mechanism 36 having a fan or the like for cooling the base 14 by blowing cold wind against the base 14, and then convey the cooled base 14 to the apparatus for performing the second etching process. When the pressed base 14 is cooled and then conveyed to the apparatus for performing the second etching process, this apparatus for performing the second etching process can immediately perform the second etching process without cooling the base 14 to a required temperature.

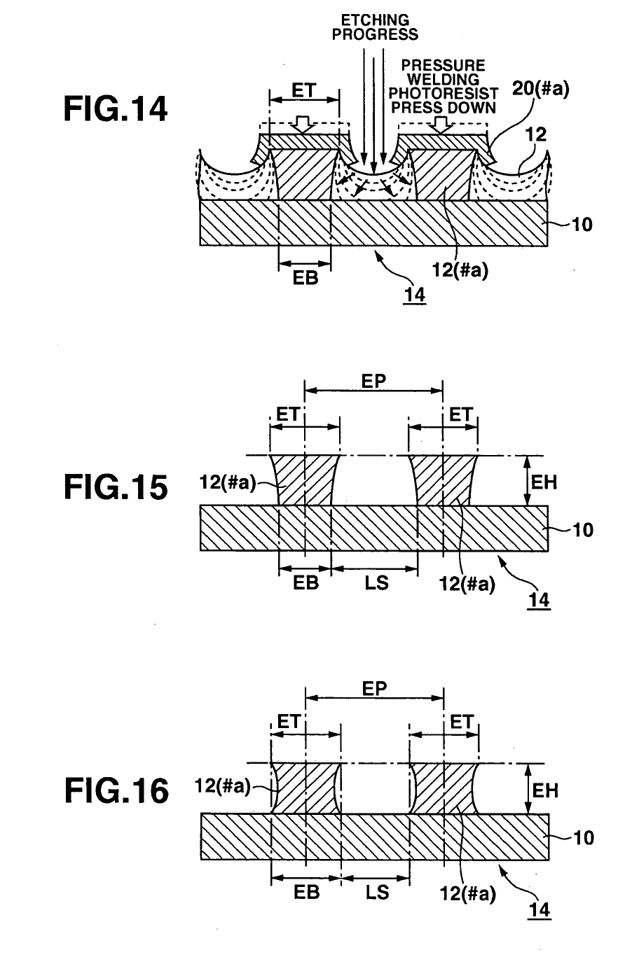

The process in step S7 is then performed by the apparatus for the second etching process. That is, this apparatus etches the pressed base 14. For example, the etching is performed by the shower etching method by using a cupric chloride-based copper etchant at a liquid temperature of 35° C. and a spray pressure of 0.25 MPa for an etching time of about 35 to 55 sec. Consequently, as shown in FIG. 14, the conductor layers 12(#a) are completely separated in accordance with wiring circuit patterns, thereby forming predetermined wiring circuit patterns.

The vertical sectional shape in the widthwise direction of each wiring circuit pattern formed is unetched, because the top and side walls of the conductor layer 12(#a) are covered with the photoresist 20(#a). Therefore, as shown in FIG. 15, the top width is larger than the bottom width (i.e., ET≧EB); at least the vertical sectional shape in the widthwise direction of the wiring circuit pattern can be formed into a “substantially inverted trapezoidal shape” or “substantially horn shape”.

Furthermore, by changing the second etching conditions, e.g., by slightly reducing the etching time to 30 to 40 sec, as shown in FIG. 16, the central portion is narrowed and the top width and bottom width are made equal (i.e., ET=EB); the vertical sectional shape-in the widthwise direction can be formed into a “hourglass shape”.

Since the vertical section in the widthwise direction of each of the wiring circuit patterns is formed into a “substantially inverted trapezoidal shape”, “substantially horn shape”, or “hourglass shape”, the shape of a spaced sandwiched between these wiring circuit patterns can be formed into a “substantially trapezoidal shape”, “substantially bowl shape”, or “barrel shape”, respectively.

Accordingly, in the space sandwiched between the formed wiring patterns, EB or the length of the side in contact with the surface of the base 14 is larger than that of the opposing side.

This means that at the same pattern pitch, the leak path length (the length of an electrical line formed by wiring pattern—polyimide surface—wiring circuit pattern) between adjacent wiring circuit patterns can be made substantially larger than that of a wiring circuit pattern formed by a subtraction method using the conventional wet etching method. Therefore, the insulating resistance between the wiring circuit patterns can be maintained higher than that of a printed circuit board formed by the conventional method.

Also, the vertical sectional area in the widthwise direction of each of the wiring circuit patterns formed by the present invention and the space area formed between them are equal, or the space area formed between the wiring circuit patterns can be made larger than the vertical sectional area in the widthwise direction of each wiring circuit pattern.

The base 14 on which the predetermined wiring circuit patterns are thus formed is cleaned and dried, where necessary, and the photoresists 20(#a) are removed (S8). Finally, a surface treatment is performed by a method such as electroplating, electroless plating, or nanopaste printing (S9), thereby completing the whole fabrication process.

In the present invention as described above, the top width ET of at least the conductor layer 12(#a) can be made equal to or larger than the bottom width EB. Accordingly, the sectional shape of a wiring pattern can be formed into a substantially inverted trapezoidal shape which cannot be formed by the conventional subtraction method. In addition, even at a fine pattern pitch, the bottoms (EB) of the individual wiring circuit patterns formed can be arranged away from each other on the surface of the base 14. Furthermore, the etching factor can be improved.

As described above, even when the wiring pitch is made fine, it is possible to realize a printed circuit board having wiring patterns which do not deteriorate the migration resistance and bonding properties.

A printed circuit board fabrication apparatus according to this embodiment uses the printed circuit board fabrication method according to this embodiment as described above. This printed circuit board fabrication apparatus is obtained by combining all of the apparatus for performing the pressing process in step S1, the apparatus for performing the photoresist coating process in step S2, the apparatus for performing the exposure process in step S3, the apparatus for performing the development process in step S4, the apparatus for performing the first etching process in step S5, the heating/pressing apparatus for performing the heating/pressing process in step S6, the apparatus for performing the second etching process in step S7, the apparatus for performing the resist removing process in step S8, and the apparatus for performing the surface treatment in step S9.

This fabrication apparatus can be a single apparatus for performing all of the plurality of steps described above. Alternatively, the apparatus for performing the first etching process and the heating/pressing apparatus can be combined into one apparatus, the heating/pressing apparatus and the apparatus for performing the second etching process can be combined into one apparatus, or the apparatus for performing the first etching process, the heating/pressing apparatus, and the apparatus for performing the second etching process can be combined into one apparatus.

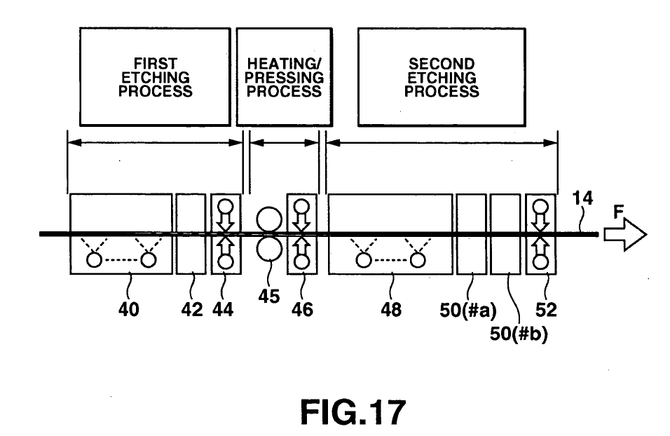

The best mode for carrying out the present invention has been explained above with reference to the accompanying drawing. However, the present invention is not limited to this arrangement. Those skilled in the art can reach various changes and modifications within the scope of claims and the range of the invented technical ideas. It is to be understood that these changes and modifications are also incorporated in the technical scope of the present invention. For example, as shown in FIG. 17, between a first etching bath 40 for performing the first etching process and a heating/pressing apparatus 45, it is possible to add a cleaning bath 42 for cleaning the base 14 having undergone the first etching process, and a dryer 44 for drying the base 14 cleaned by the cleaning bath 42. It is also possible to add a cooler 46 for cooling the base 14 heated and pressed by the heating/pressing apparatus 45. Furthermore, on the downstream side of a second etching bath 48 for performing the second etching process, it is possible to add cleaning baths 50(#a) and 50(#b) for cleaning the base 14 having undergone the second etching process, and a dryer 52 for drying the base 14 cleaned by the cleaning baths 50(#a) and 50(#b). That is, it is to be understood that the present invention also incorporates a fabrication method in which necessary steps are appropriately added to the aforementioned steps, and a fabrication apparatus additionally having apparatuses for implementing these additional steps.

The above embodiment is explained by taking a light-transmitting flexible board as an example. However, it is also possible to use a common non-light-transmitting printed wiring board, a so-called rigid board, such as FR4 or FR5. In this case, the above-described roll-to-roll (R-to-R) continuous production method cannot be used because the board is thick, but a batch production method can be used.

Also, the heating/pressing rollers 26 are used to press and heat the resist, but the present invention is not limited to this arrangement. That is, the photoresist 20 can be similarly pressed by using a commonly used press (naturally capable of heating and pressing) without using the heating/pressing rollers 26. When the press is used, boards 900 to 1,200 mm wide can be evenly heated and pressed. In addition, boards to be processed can be stacked and simultaneously processed.

### Second Embodiment

The second embodiment of the present invention will be described below.

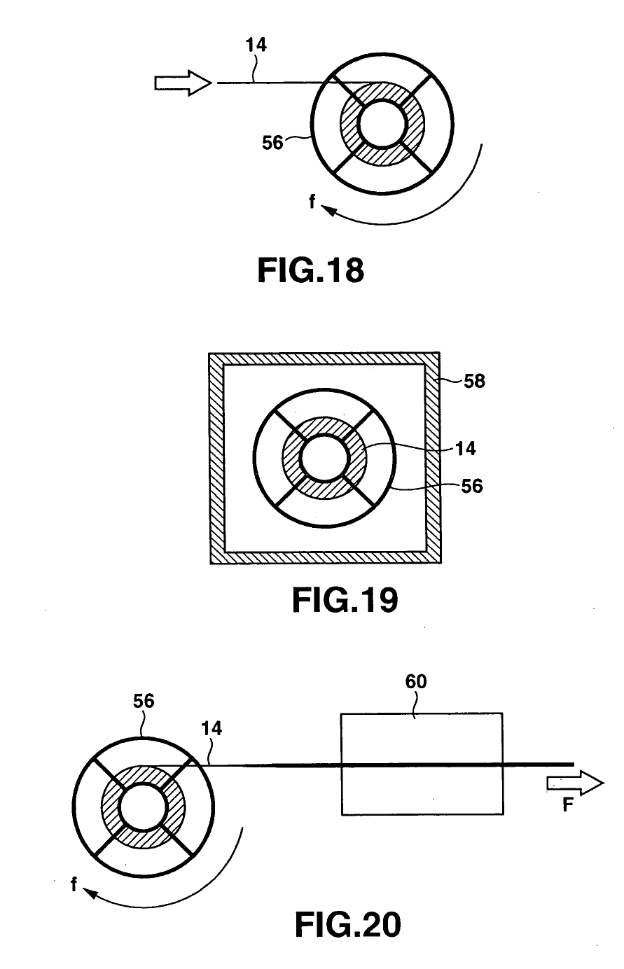

The same reference numerals as in the first embodiment denote the same parts in FIGS. 18 to 20, so a detailed explanation thereof will be omitted, and only differences will be explained.

This embodiment is a modification of the heating/pressing apparatus described in the first embodiment.

That is, a heating/pressing apparatus according to this embodiment includes a reel rotating mechanism (not shown) which rotates a reel 56 in a rotational direction f as shown in FIG. 18, a constant-temperature bath 58 which holds the temperature of the reel 56 as shown in FIG. 19, and a cooler 60 which cools a base 14 unwound from the reel 56 as shown in FIG. 20.

The reel rotating mechanism (not shown) rotates the reel 56 in the rotational direction f to wind, on the reel 56, the tape-like base 14 supplied from an apparatus for performing a first etching process, while giving tension in the longitudinal direction of the base 14. When the supplied base 14 is completely wound on the reel 56, the reel 56 is detached from the reel rotating mechanism (not shown) and placed in the constant-temperature bath 58 for a predetermined time. The constant-temperature bath 58 holds its internal temperature equal to or higher than the softening temperature of a photoresist 20 and lower than the softening temperature of a conductor layer 12. Consequently, the base 14 which is given tension when wound on the reel 56 is heated to a temperature equal to or higher than the softening temperature of the photoresist 20 and lower than the softening temperature of the conductor layer 12. These tension and heat achieve the same effects as obtained by the heating/pressing rollers 26(#a) and 26(#b) in the first embodiment. As a consequence, the sectional shape of the base 14 changes from a sectional shape shown in FIG. 11 to a sectional shape as shown in FIG. 12.

After a predetermined time has elapsed, the reel 56 is taken out of the constant-temperature bath 58. As shown in FIG. 20, the base 14 is continuously unwound from the reel 56 and introduced into the cooler 60 by rotating the reel 56 in the rotational direction f. The cooler 60 cools the introduced base 14. The thus cooled base 14 is continuously fed to the apparatus which includes a second etching bath 48, cleaning bath 50, and dryer 52 and performs a second etching process.

The function of the heating/pressing apparatus according to this embodiment having the above arrangement will be described below.

The tape-like base 14 supplied from the apparatus for performing the first etching process is wound on the reel 56, while tension is given in the longitudinal direction of the base 14, by rotating the reel 56 in the rotational direction f. When the base 14 is thus wound on the reel 56, the reel 56 is detached from the reel rotating mechanism and placed in the constant-temperature bath 58 for a predetermined time.

The internal temperature of the constant-temperature bath 58 is held equal to or higher than the softening temperature of the photoresist 20 and lower than the softening temperature of the conductor layer 12. In the constant-temperature bath 58, therefore, the base 14 which is given tension when wound on the reel 56 is heated to a temperature equal to or higher than the softening temperature of the photoresist 20 and lower than the softening temperature of the conductor layer 12. As a consequence, the sectional shape of the base 14 changes from the sectional shape shown in FIG. 11 to the sectional shape as shown in FIG. 12. The predetermined time is determined by checking beforehand a time during which the sectional shape of the base 14 changes from the sectional shape shown in FIG. 11 to the sectional shape as shown in FIG. 12.

After a predetermined time has elapsed, the reel 56 is taken out of the constant-temperature bath 58. After that, the base 14 is continuously unwound from the reel 56 and introduced into the cooler 60 by a conveyor mechanism (not shown), and cooled in the cooler 60. The thus cooled base 14 is continuously fed to the apparatus which includes the second etching bath 48, cleaning bath 50, and dryer 52 and performs the second etching process.

Accordingly, the heating/pressing apparatus having the arrangement as described above can also achieve the same effects as the first embodiment.

### Third Embodiment

The third embodiment of the present invention will be described below.

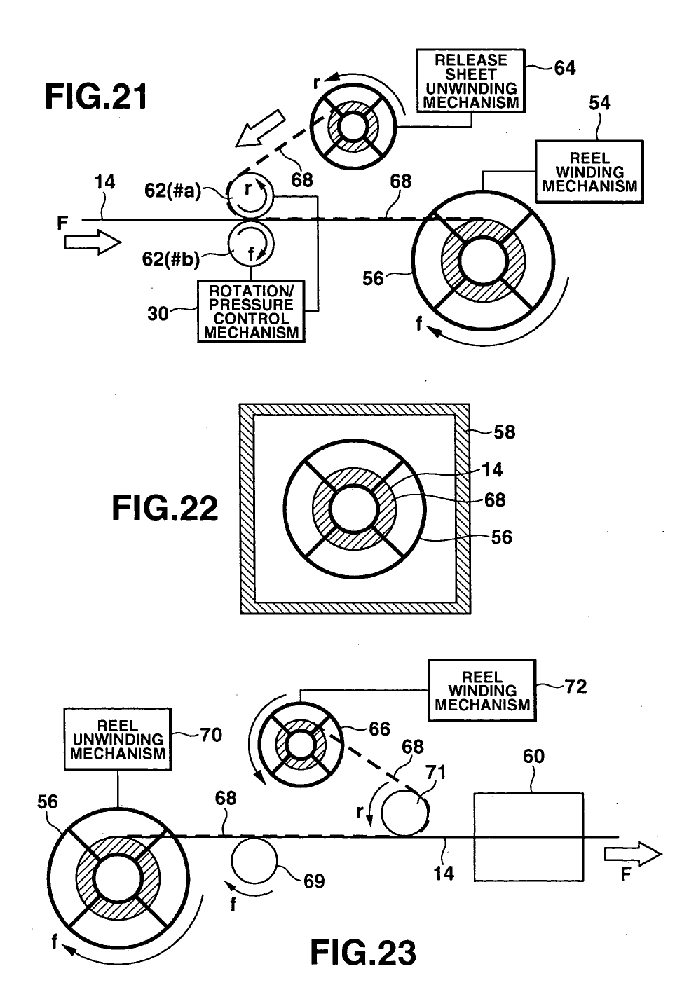

The same reference numerals as in the first and second embodiments denote the same parts in FIGS. 21 to 23, so a detailed explanation thereof will be omitted, and only differences will be explained.

This embodiment is a modification of the heating/pressing apparatus described in the second embodiment.

That is, a heating/pressing apparatus according to this embodiment is suited to winding a release sheet, such as a Polyethylen trephtalate sheet with a release coating, on the surface of a photoresist 20 of a base 14. This apparatus comprises a conveyor mechanism (not shown), a pair of opposing pressing rollers 62(#a) and 62(#b), rotation/pressure control mechanism 30, release sheet unwinding mechanism 64, and reel winding mechanism 54 shown in FIG. 21, a constant-temperature bath 58 shown in FIG. 22, and a reel unwinding mechanism 70, release sheet winding mechanism 72, and cooler 60 shown in FIG. 23.

The base 14 supplied from an apparatus for performing a first etching process is introduced, with the surface of the photoresist 20 facing up, between the pair of pressing rollers 62(#a) and 62(#b) by the conveyor mechanism (not shown).

The release sheet unwinding mechanism 64 rotates a reel 66 having a release sheet 68 wound on it in a rotational direction r, thereby unwinding the release sheet 68 so as to be introduced between the pair of pressing rollers 62(#a) and 62(#b). The release sheet 68 is so supplied, via the upper pressing roller 62(#a), as to cover the upper surface of the base 14 which is similarly introduced between the pair of pressing rollers 62(#a) and 62(#b).

The pair of pressing rollers 62(#a) and 62(#b) are the same as the heating/pressing rollers 26(#a) and 26(#b) in the first embodiment except that the rollers 62(#a) and 62(#b) have no heating function. The rotation/pressure control mechanism 30 controls the pressure which the pair of pressing rollers 62(#a) and 62(#b) apply to the release sheet 68 and base 14 introduced between them. The rotation/pressure control mechanism 30 also controls the rotational direction r of the roller 62(#a), and a rotational direction f and the speed of the roller 62(#b).

When the base 14 and release sheet 68 are introduced between the two rollers 62(#a) and 62(#b) having the above arrangement, the two rollers 62(#a) and 62(#b) press the release sheet 68 against the surface of the photoresist 20 of the base 14. After that, the base 14 having the release sheet 68 pressed against the surface of the photoresist 20 is fed along a conveyance direction F.

The reel winding mechanism 54 rotates the reel 56 in the rotational direction f to wind, on the reel 56, the tape-like base 14 having the release sheet 68 pressed against it, while giving tension in the longitudinal direction of the base 14 and release sheet 68. When the base 14 is completely wound on the reel 56, the reel 56 is detached from the reel winding mechanism 54, and placed in the constant-temperature bath 58 for a predetermined time as shown in FIG. 22. The constant-temperature bath 58 holds its internal temperature equal to or higher than the softening temperature of the photoresist 20 and lower than the softening temperature of a conductor layer 12. Therefore, as in the second embodiment, the base 14 which is given tension when wound on the reel 56 is heated to a temperature equal to or higher than the softening temperature of the photoresist 20 and lower than the softening temperature of the conductor layer 12, although the release sheet 68 is placed on the surface of the photoresist 20. As a consequence, the sectional shape of the base 14 changes from a sectional shape shown in FIG. 11 to a sectional shape as shown in FIG. 12.

After a predetermined time has elapsed, the reel 56 is taken out of the constant-temperature bath 58, and set in the reel unwinding mechanism 70 as shown in FIG. 23. The reel unwinding mechanism 70 continuously unwinds the base 14 wound on the reel 56 and having the release sheet 68 toward the cooler 60. Generally, when the base 14 wound into a plurality of turns on the reel 56 is to be unwound from the reel 56, the lower surface of the base 14 of the outside turn and the upper surface of the base 14 of the inside turn are in direct contact with each other and adhered in the reel 56. This sometimes makes smooth unwinding impossible or causes removing of the photoresist 20. In this embodiment, however, the release sheet 68 exists between the lower surface of the base 14 of the outside turn and the upper surface of the base 14 of the inside turn in the reel 56. This smoothes unwinding from the reel 56, and also prevents removing of the photoresist 20.

The thus unwound base 14 with the release sheet 68 is conveyed in the conveyance direction F by a conveyor roller 69 which rotates in the rotational direction f. The release sheet 68 is wound on the reel 66 by the release sheet winding mechanism 72 via a conveyor roller which rotates in the rotational direction r. The base 14 alone is introduced into the cooler 60.

The cooler 60 continuously cools the introduced tape-like base 14. The thus cooled base 14 is continuously fed to an apparatus which includes a second etching bath 48, cleaning bath 50, and dryer 52 and performs a second etching process.

The function of the heating/pressing apparatus according to this embodiment having the above arrangement will be described below.

The base 14 supplied from the apparatus for performing the first etching process is introduced, with the surface of the photoresist 20 facing up, between the pair of pressing rollers 62(#a) and 62(#b) by the conveyor mechanism (not shown).

The release sheet unwinding mechanism 64 rotates the reel 66 having the release sheet 68 wound on it in the rotational direction r, thereby unwinding the release sheet 68 so as to be introduced between the pair of pressing rollers 62(#a) and 62(#b). As a result, the upper surface of the base 14 which is similarly introduced between the pair of pressing rollers 62(#a) and 62(#b) is covered with the release sheet 68.

When the base 14 and release sheet 68 are introduced between the two rollers 62(#a) and 62(#b), the two rollers 62(#a) and 62(#b) press the release sheet 68 against the surface of the photoresist 20 of the base 14. The base 14 having the release sheet 68 pressed against it is wound while tension is given by the reel 56.

When the base 14 with the release sheet 68 is completely wound on the reel 56, the reel 56 is detached from the reel winding mechanism 54, and placed in the constant-temperature bath 58 for a predetermined time. The internal temperature of the constant-temperature bath 58 is held equal to or higher than the softening temperature of the photoresist 20 and lower than the softening temperature of the conductor layer 12. Therefore, as in the second embodiment, the base 14 with the release sheet 68 is heated to a temperature equal to or higher than the softening temperature of the photoresist 20 and lower than the softening temperature of the conductor layer 12, while the tension given when the base 14 is wound on the reel 56 is kept applied. As a consequence, the sectional shape of the base 14 changes from the sectional shape shown in FIG. 11 to the sectional shape as shown in FIG. 12.

After a predetermined time has elapsed, the reel 56 is taken out of the constant-temperature bath 58, and set in the reel unwinding mechanism 70. The reel unwinding mechanism 70 continuously unwinds the base 14 wound on the reel 56 and having the release sheet 68 toward the cooler 60. Generally, when the base 14 wound into a plurality of turns on the reel 56 is to be unwound from the reel 56, the lower surface of the base 14 of the outside turn and the upper surface of the base 14 of the inside turn are in direct contact with each other and adhered in the reel 56. This sometimes makes smooth unwinding from the reel 56 impossible. In this embodiment, however, the release sheet 68 exists between the lower surface of the base 14 of the outside turn and the upper surface of the base 14 of the inside turn in the reel 56. This smoothes unwinding from the reel 56, and also prevents removing of the photoresist 20 during unwinding.

Of the thus unwound base 14 with the release sheet 68, the release sheet 68 is wound on the reel 66 by the release sheet winding mechanism 72, and the base 14 alone is introduced into the cooler 60 and cooled in it. After that, the cooled base 14 is continuously fed to the apparatus which includes the second etching bath 48, cleaning bath 50, and dryer 52 and performs the second etching process.

As described above, the heating/pressing apparatus of this embodiment can perform the heating/pressing process while the release sheet 68 is placed on the photoresist 20 of the base 14. Therefore, the base 14 can be smoothly unwound from the reel 56 while removing of the photoresist 20 is prevented. This achieves the same effects as in the first embodiment.

The above embodiment is explained by taking a light-transmitting flexible board as an example. However, it is also possible to use a common non-light-transmitting printed wiring board, a so-called rigid board, such as FR4 or FR5. In this case, the above-described roll-to-roll (R-to-R) continuous method cannot be used because the board is thick, but a single wafer method (batch method) can be used.

Also, the pressing rollers 62 are used to press and heat the resist, but the present invention is not limited to this arrangement. That is, the photoresist 20 can be similarly pressed by using a commonly used press (naturally capable of heating and pressing) without using the pressing rollers 62. When the press is used, boards 900 to 1,200 mm wide can be evenly heated and pressed. In addition, boards to be processed can be stacked and simultaneously processed.

Additional advantages and modifications will readily occur to those skilled in the art. Therefore, the invention in its broader aspects is not limited to the specific details and representative embodiments shown and described herein. Accordingly, various modifications may be made without departing from the spirit and scope of the general inventive concept as defined by the appended claims and their equivalents.

1. A wiring circuit pattern formed by forming a resin resist pattern film on a conductor layer of a base of a printed circuit board in which at least an insulating layer and the conductor layer are stacked on at least one surface of the base, and performing wet etching by using the formed resin resist pattern film as an etching resist,
wherein a width of a top of the wiring circuit pattern is larger than a width of a bottom thereof.

2. A pattern according to claim 1, wherein the board is formed by impregnating glass fibers with a resin such as an epoxy resin, and has no light transmittance.

3. A pattern according to claim 1, wherein the board is made of a material selected from the group consisting of polyimide, Polyethylene-Terephtalate, and Polyethylene Naphtalate, and has light transmittance.

4. A wiring circuit pattern formed by forming a resin resist pattern film on a conductor layer of a base of a printed circuit board in which at least an insulating layer and the conductor layer are stacked on at least one surface of the base, and performing wet etching by using the formed resin resist pattern film as an etching resist,
wherein at least a vertical sectional shape in a widthwise direction of the wiring circuit pattern is a substantially inverted trapezoidal shape.

5. A wiring circuit pattern formed by forming a resin resist pattern film on a conductor layer of a base of a printed circuit board in which at least an insulating layer and the conductor layer are stacked on at least one surface of the base, and performing wet etching by using the formed resin resist pattern film as an etching resist,
wherein at least a vertical sectional shape in a widthwise direction of the wiring circuit pattern is a substantially horn shape.

6. A wiring circuit pattern formed by forming a resin resist pattern film on a conductor layer of a base of a printed circuit board in which at least an insulating layer and the conductor layer are stacked on at least one surface of the base, and performing wet etching by using the formed resin resist pattern film as an etching resist,
wherein at least a vertical sectional shape in a widthwise direction of the wiring circuit pattern is a substantially hourglass shape.

7. A printed wiring board formed by forming a resin resist pattern film on a conductor layer of a base of a printed circuit board in which at least an insulating layer and the conductor layer are stacked on at least one surface of the base, and performing wet etching by using the formed resin resist pattern film as an etching resist,
wherein at least a vertical sectional shape in a widthwise direction of the printed wiring board is a substantially inverted trapezoidal shape, and a space formed between wiring circuit patterns has a substantially trapezoidal shape.

8. A board according to claim 7, wherein an area of the substantially trapezoidal shape is not less than an area of the substantially inverted trapezoidal shape.

9. A printed wiring board formed by forming a resin resist pattern film on a conductor layer of a base of a printed circuit board in which at least an insulating layer and the conductor layer are stacked on at least one surface of the base, and performing wet etching by using the formed resin resist pattern film as an etching resist,
wherein at least a vertical sectional shape in a widthwise direction of the printed wiring board is a substantially horn shape, and a space formed between wiring circuit patterns has a substantially bowl shape.

10. A board according to claim 9, wherein an area of the substantially bowl shape is not less than an area of the substantially horn shape.

11. A printed wiring board formed by forming a resin resist pattern film on a conductor layer of a base of a printed circuit board in which at least an insulating layer and the conductor layer are stacked on at least one surface of the base, and performing wet etching by using the formed resin resist pattern film as an etching resist,
wherein at least a vertical sectional shape in a widthwise direction of the printed wiring board is a substantially hourglass shape, and a space formed between wiring circuit patterns has a substantially barrel shape.

12. A board according to claim 11, wherein an area of the substantially barrel shape is not less than an area of the substantially hourglass shape.

13. A printed circuit board fabrication apparatus comprising:
resin resist pattern forming means for forming a resin resist pattern film on a conductor layer of a base of a printed circuit board obtained by stacking at least an insulating layer and the conductor layer;
first etching means for etching away a portion of a film thickness of the conductor layer by using the resin resist pattern film formed by the resin resist pattern forming means as an etching resist;
pressing means for heating the base, from which the portion of the film thickness of the conductor layer is etched away by the first etching means, to a temperature not less than a softening temperature of the resin resist pattern film, and pressing the resin resist pattern film against the conductor layer, thereby allowing the resin resist pattern film to cover surfaces of the conductor layer in contact with the resin resist pattern film; and
second etching means for etching away the rest of the film thickness of the conductor layer from which the portion of the film thickness is etched away by the first etching means, thereby forming a predetermined wiring circuit pattern by the conductor layer.

14. A printed circuit board fabrication method comprising:
a resin resist pattern formation step of forming a resin resist pattern film on a conductor layer of a base of a printed circuit board obtained by stacking at least an insulating layer and the conductor layer;
a first etching step of etching away a portion of a film thickness of the conductor layer by using the resin resist pattern film formed in the resin resist pattern formation step as an etching resist;
a pressing step of heating the base, from which the portion of the film thickness of the conductor layer is etched away in the first etching step, to a temperature not less than a softening temperature of the resin resist pattern film, and pressing the resin resist pattern film against the conductor layer, thereby allowing the resin resist pattern film to cover surfaces of the conductor layer in contact with the resin resist pattern film; and
a second etching step of etching away the rest of the film thickness of the conductor layer from which the portion of the film thickness is etched away in the first etching step, thereby forming a predetermined wiring circuit pattern by the conductor layer.

15. A printed circuit board fabrication method comprising:
a resin resist pattern formation step of forming a resin resist pattern film on a conductor layer of a tape-like base of a printed circuit board obtained by stacking at least an insulating layer and the conductor layer;
a first etching step of etching away a portion of a film thickness of the conductor layer by using the resin resist pattern film formed in the resin resist pattern formation step as an etching resist;
a winding step of winding the tape-like base on a reel while applying tension in a longitudinal direction of the base;
a pressing step of heating the base wound on the reel such that the resin resist pattern film is heated to a temperature not less than a softening temperature thereof, thereby softening the resin resist pattern film, and allowing the softened resin resist pattern film to cover surfaces in contact with the resin resist pattern film by the tension; and
a second etching step of etching away the rest of the film thickness of the conductor layer from which the portion of the film thickness is etched away in the first etching step, thereby forming a predetermined wiring circuit pattern by the conductor layer.

16. A printed circuit board fabricated by a printed circuit board fabrication method cited in claim 14 or 15.
